(19) United States
(12) Patent Application Publication
(10) Pub. No.: US 2026/0267504 A1
(43) Pub. Date: Sep. 10, 2026

(54) METHOD OF PROVIDING A MODIFIABLE GRAPHICAL USER INTERFACE FOR CONTROLLING A LOCK-IN AMPLIFIER

(71) Applicant: Rohde & Schwarz GmbH & Co. KG, Muenchen (DE)

(72) Inventors: Tony PRAT, Zürich (CH); Mehdi ALEM, Zürich (CH); Roger BISCHOF, Zürich (CH)

(21) Appl. No.: 19/541,470

(22) Filed: Feb. 17, 2026

(30) Foreign Application Priority Data
Mar. 10, 2025 (DE) 10 2025 108 969.8

(51) Int. Cl. G06F 3/04886; G06F 3/0482; G06F 3/0488

(52) U.S. Cl. CPC G06F 3/04886; G06F 3/0482; G06F 3/0488

(57) ABSTRACT

The present disclosure relates to a method of providing a modifiable graphical user interface, GUI, for controlling a lock-in amplifier. The GUI has a work surface and allows the user to add control elements to the work surface to obtain an application-specific GUI which is specifically adapted to a particular measurement application of the lock-in amplifier.

### CROSS-REFERENCE(S) TO RELATED APPLICATION(S)

This application claims priority to German Application No. 10 2025 108 969.8, filed on Mar. 10, 2025, the entire disclosure of which is enclosed herein in its entirety.

### FIELD OF THE DISCLOSURE

The present disclosure relates to a method of providing a modifiable graphical user interface for controlling a lock-in amplifier. The present disclosure further relates to a lock-in amplifier which is designed to execute such a method.

### BACKGROUND

Lock-in amplifiers are measurement instruments used to filter out a weak alternating signal from a noisy background. They enable precise measurements by extracting the signal at a specific reference frequency. Alternating voltages of other frequencies, as well as direct voltages and unwanted background noise, are suppressed.

The prior art discloses solutions for controlling lock-in amplifiers the respective user interfaces of which make all control options of the device directly available, which entails a high degree of complexity and may lead to complex handling. Alternatively, there are solutions with predefined application-specific user interfaces. However, due to the limitation to predefined applications, these solutions lack the desired flexibility.

Thus, there is a need for overcoming the disadvantages known from the prior art.

### SUMMARY

According to the present disclosure, the object, or others, is achieved by a method of providing a modifiable graphical user interface (GUI) for controlling a lock-in amplifier. In an embodiment, the GUI has a work surface and allows the user to add control elements to the work surface to obtain an application-specific GUI which is specifically adapted to a particular measurement application of the lock-in amplifier.

This allows the user to adapt the GUI such that precisely the control elements required for the respective measurement application are displayed and no unnecessary complexity arises from the display of superfluous control options. Furthermore, this allows the user to build and adapt the GUI in a purposeful manner without being limited to predefined measurement applications. In other words, maximum flexibility is achieved while minimizing the complexity of the GUI, so that even untrained or less experienced individuals can operate the lock-in amplifier via the GUI.

In an embodiment, the control elements may be assigned to various components of a measurement setup with which the measurement application is to be implemented. This gives the user control over which components of the measurement setup are to be controllable via the GUI.

For example, the control elements may be assigned to an input terminal of a device, a signal processing unit, a control unit, an input signal, and/or an output terminal of the device. The input and output terminal is typically a physical terminal on the device. For example, the input signal can be fed into the device via the input terminal. The signal processing unit may also be specifically designed as a signal analysis unit. The device may be the lock-in amplifier itself or a device connected to the lock-in amplifier.

One aspect provides, for example, that the control elements are displayed on the work surface as flat geometric figures. The control elements can thus be presented to the user in a clear manner. For example, the control elements may be visible as rectangles (“blocks”). The control elements may also be assigned to specific groups, wherein each group has a predefined geometric figure, such as rectangles, triangles, circles, etc. The different geometric figures allow the operator to directly recognize which group of control elements the respective control element belongs to.

In addition, the control elements may be displayed as connected to each other by lines (dashed, solid, etc.), if necessary. This allows the functional relationships between the control elements to be made clear to the user. The respective lines may be provided with arrows at the ends if a specific direction is to be represented, for example in the case of a unidirectional connection.

A further aspect provides, for example, that control elements which have an observable influence in the current operating state of the lock-in amplifier are automatically added to the work surface. Accordingly, the GUI can automatically adapt to the current operating state. This makes it possible to reduce the need for manual configuration without limiting the flexibility of the user in designing the GUI.

In addition or alternatively, at least one additional control element may be automatically added to the work surface together with a control element selected by the user if a component assigned to the additional control element is required for the function of the selected control element. It is thus possible to speed up and simplifies the correct setup of a suitable GUI for the desired measurement. In addition, the risk of misconfiguration can be reduced. The additional control element may be displayed on the work surface as connected to the selected control element.

As a concrete example, when adding a control element assigned to a demodulator of the lock-in amplifier, a control element assigned to a signal input of the demodulator may be automatically added.

According to a further aspect, the GUI, for example, enables the user to design a measurement process, validate a measurement configuration, and/or perform a measurement. Thus, the adaptable GUI may provide support for the entire measurement process from planning to execution, thereby increasing the efficiency and accuracy of measurements. Here, the design of the measurement process typically also includes the design of the signal flow.

For example, to reduce setup time, the GUI may provide the user with templates for multiple measurement applications, the templates each including specific control elements necessary for the respective measurement application. Frequently occurring measurement applications may thus be initiated particularly efficiently. After the selection of a template by the user, the correspondingly necessary control elements can be automatically added to the work surface. Since the GUI is adaptable, the user may use a template as a starting point for creating an own GUI for a similar measurement application.

Furthermore, the GUI can allow the user to select that at least one signal is to be sampled, which flows through a component assigned to a selected control element. In addition or alternatively, the GUI may allow to select that at least one signal is to be sampled, which flows between two components assigned to two selected control elements. This flexible signal sampling enables detailed analysis and optimization of the signal flow within the measurement setup.

The present disclosure also provides a computer-readable storage medium which stores instructions which, when executed by a computer processor, cause the computer processor to execute any method according to the present disclosure, i.e., the method(s) described above.

Furthermore, the above-mentioned object, or others, is achieved according to the present disclosure by a lock-in amplifier including the aforementioned computer-readable storage medium and/or a processor set up to execute any method according to the present disclosure.

The advantages and features mentioned in connection with the method also apply accordingly to the computer-readable storage medium and the lock-in amplifier or can be transferred thereto accordingly.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 shows a schematic representation of a measurement setup with a lock-in amplifier;

FIG. 2 shows a graphical user interface according to an embodiment of the present disclosure which has been adapted for a lock-in measurement with an external signal generator;

FIG. 3 shows a graphical user interface according to an embodiment of the present disclosure, in which control elements are displayed in an expanded view;

FIG. 4 shows a graphical user interface according to an embodiment of the present disclosure which has been adapted for a lock-in measurement at multiple frequencies;

FIG. 5 shows a graphical user interface according to an embodiment of the present disclosure which has been adapted for a multi-channel measurement; and

FIG. 6 shows a graphical user interface according to an embodiment of the present disclosure, in which signal sampling has been activated for a control element.

### DETAILED DESCRIPTION

The detailed specification set forth below in connection with the accompanying drawings, in which the same reference numerals refer to the same elements, is intended as a description of various embodiments of the disclosed subject matter and is not intended to represent the only embodiments. Each embodiment described in this disclosure merely serves as an example or illustration and is not be interpreted as being preferred or advantageous over other embodiments. The illustrative examples given herein are not intended to be exhaustive or to limit the claimed subject matter to the disclosed specific forms.

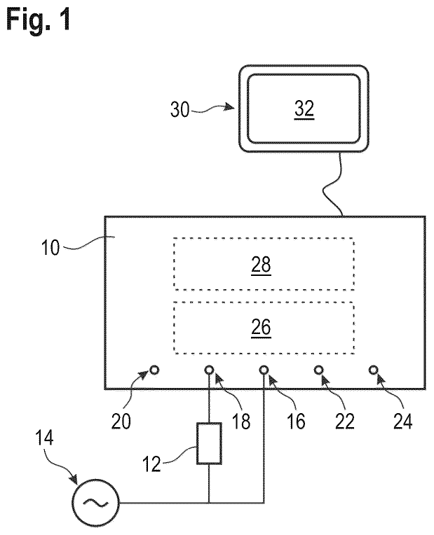

FIG. 1 shows a schematic representation of a measurement setup with a lock-in amplifier 10. In the example shown, the measurement setup is designed to perform a measurement on a device under test (DUT 12) using an external signal generator 14.

For this purpose, the external signal generator 14 is connected, on the one hand, directly to an aux input terminal 16 of the lock-in amplifier 10 and, on the other hand, to the DUT 12. The DUT 12 is in turn connected to a signal input terminal 18 of the lock-in amplifier 10. The further terminals shown of the lock-in amplifier 10 are a trigger input terminal 20, a signal output terminal 22, and an aux output terminal 24.

In the embodiment shown, the lock-in amplifier 10 also has an analog-to-digital converter 26 and an electronic circuit 28. The analog-to-digital converter 26 serves to provide input signals in digitized form to the electronic circuit 28. Digital signal processing can then be performed by the electronic circuit 28. In an embodiment, the electronic circuit 28 in the example shown is a field programmable gate array (FPGA).

For interaction with a user, the lock-in amplifier 10 is connected to a user device 30. The connection is implemented, for example, via USB or Ethernet. The user device 30 can be a computer or a mobile device. It can therefore be, for example, a desktop computer, a notebook, a tablet computer, or a smartphone.

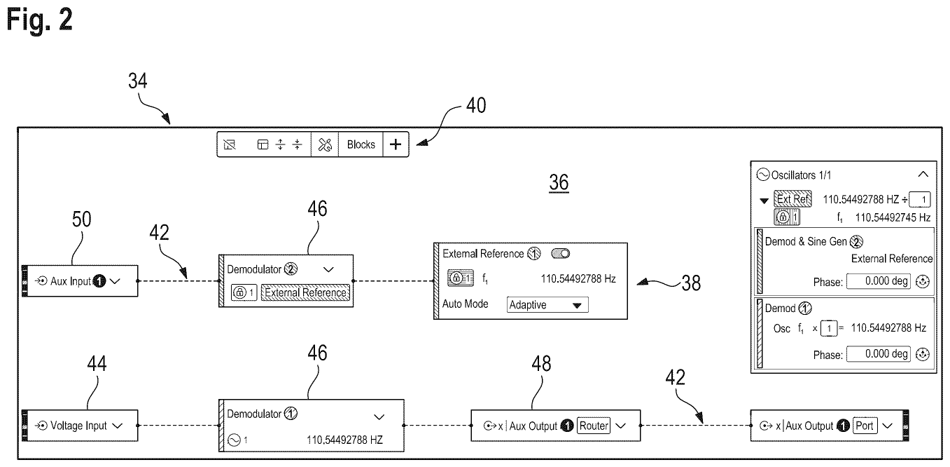

The user device has a screen 32 on which a graphical user interface (GUI) 34, (see FIGS. 2 to 6) can be displayed.

FIG. 2 shows a modifiable GUI 34 for controlling a lock-in amplifier 10. In the example shown, the GUI 34 is already set up for a lock-in measurement with an external signal generator 14. The GUI 34 can, for example, be used in the measurement setup shown in FIG. 1.

The GUI 34 has a work surface 36 and allows the user to add one or more control element(s) 38 to the work surface 36. A corresponding add button 40 is provided for this purpose. This allows the user to obtain an application-specific GUI 34 which is specifically adapted to a particular measurement application of the lock-in amplifier 10. In the example shown, the control elements 38 are represented as rectangles (“blocks”).

The control elements 38 are assigned to various components of the measurement setup with which the measurement application is to be implemented. Some of the control elements 38 are connected by lines 42, which visualize the functional relationships between the components.

Specifically, in the lower area of the work surface 36, a signal input block 46 is connected to a first demodulator block 44, which in turn has a connection to an aux output block 48. In the middle of the work surface 36, an aux input block 50 can be seen, which is connected to a second demodulator block 46.

Some of the control elements 38 are respectively assigned to independent physical components of the lock-in amplifier 10, while other control elements 38 refer to components provided by the electronic circuit 28 of the lock-in amplifier 10.

For example, the signal input block 44 and the aux input block 48 represent the signal input terminal 18 and the aux input terminal 16 of the lock-in amplifier 10, respectively. The two demodulator blocks 46 represent demodulators provided by the electronic circuit 28.

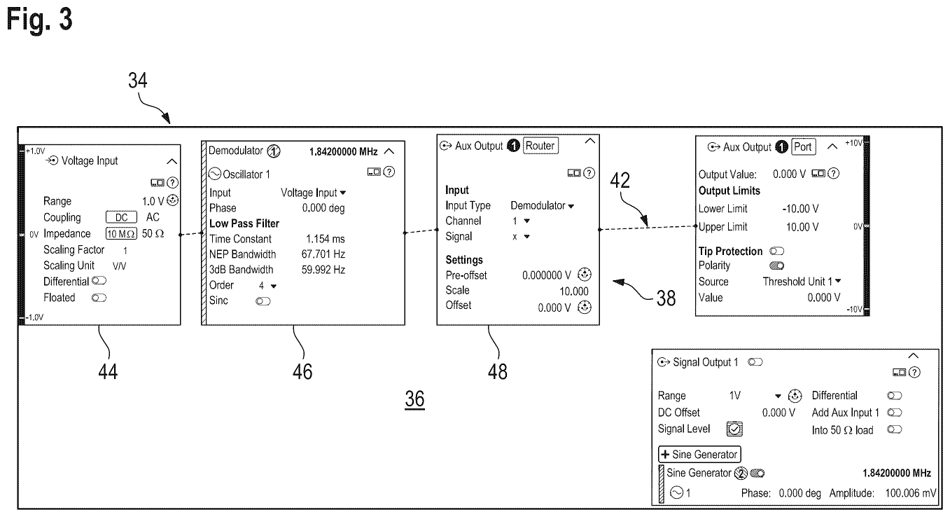

Individual control elements 38 can be transferred to an expanded view, which provides access to detailed setting options for the respective component. For this purpose, a drop-down button 52 is respectively provided in the example shown. FIG. 3 shows control elements 38 in an expanded view, the signal input block 44 and the first demodulator block 46, for example.

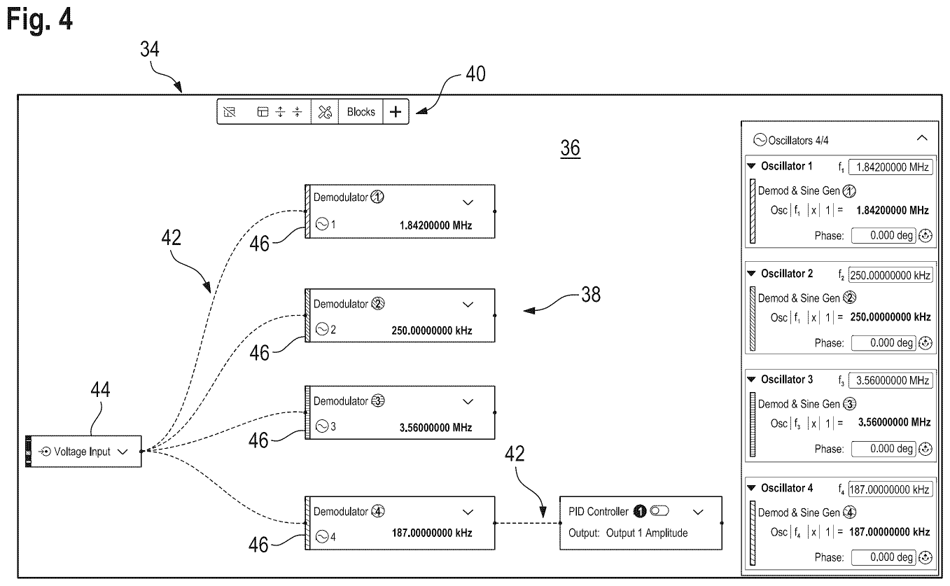

FIG. 4 shows a modifiable GUI 34 which has been adapted by a user for performing a lock-in measurement at multiple frequencies. Accordingly, four demodulator blocks 46 have been added to the work surface 36, each of which is connected to a signal input block 44. This provides the user with a clear GUI 34 for simultaneous measurement at four different frequencies.

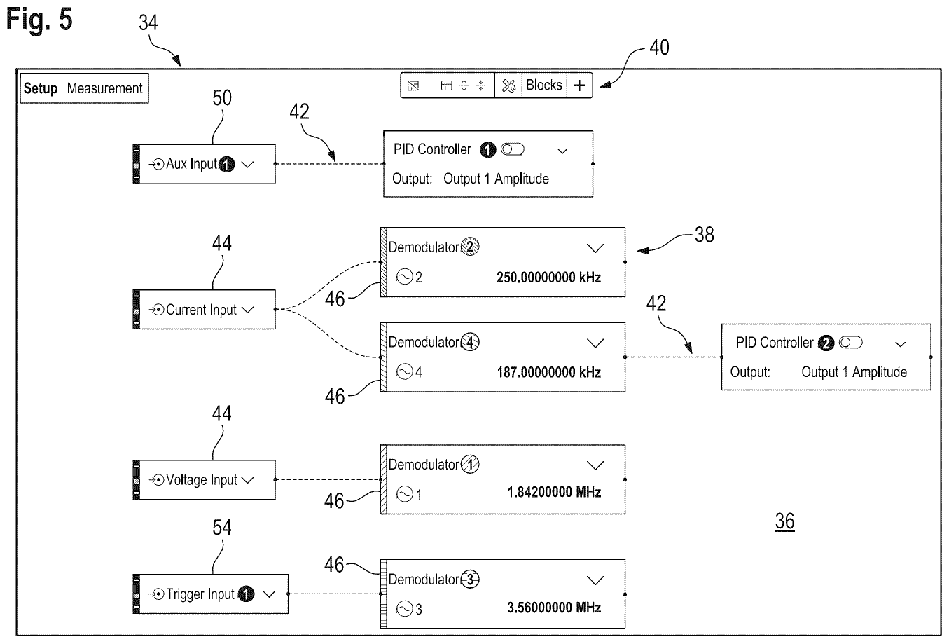

FIG. 5 shows a modifiable GUI 34 which has been adapted by a user for performing a multi-channel measurement. Accordingly, two signal input blocks 44 have been added to the work surface 36, each of which is connected to one or two demodulator blocks 46. In addition, a trigger input block 54 has been added, which is assigned to the trigger input terminal 20 of the lock-in amplifier 10.

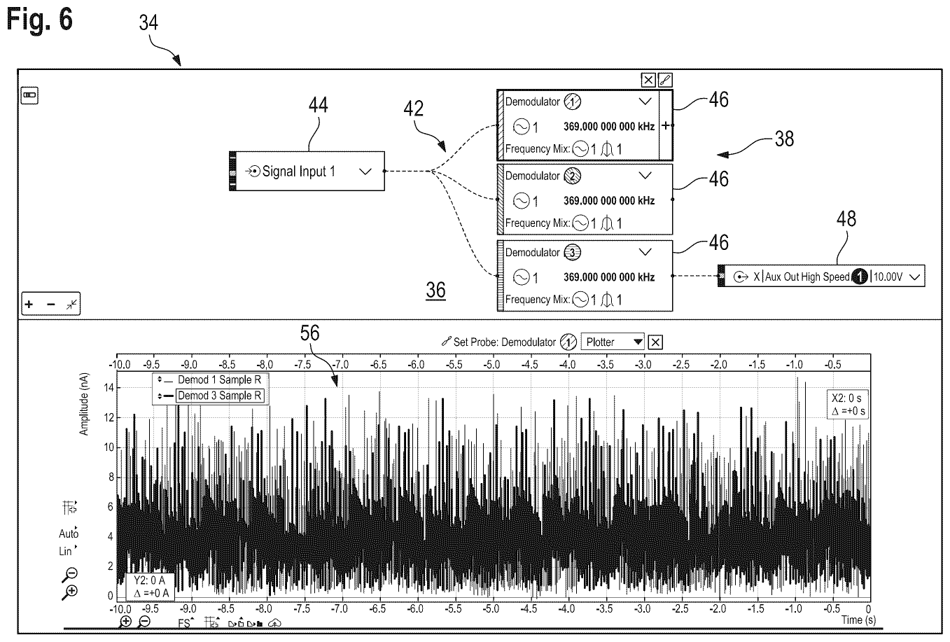

Furthermore, the modifiable GUI 34 allows signals to be sampled at or between selected blocks, for example as shown in FIG. 6. In the example shown, the user has activated a sampling function for the topmost of the three demodulator blocks 46. The output of the sampled values can be displayed, for example, as a graphical representation 56, as shown in the lower part of the work surface 36. Specifically, an amplitude of the demodulator signal is visualized there as a function of time.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be used synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a graphics processing unit (GPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

Of course, in an embodiment, two or more of these components, or parts thereof, can be integrated or share hardware and/or software, circuitry, etc. In an embodiment, these components, or parts thereof, may be grouped in a single location or distributed over a wide area. In circumstances where the components are distributed, the components are accessible to each other via communication links.

In an embodiment, one or more of the components of the measurement setup, etc., referenced above include circuitry programmed to carry out one or more steps or actions of any of the methods disclosed herein. In an embodiment, one or more computer-readable media associated with or accessible by such circuitry contains computer readable instructions embodied thereon that, when executed by such circuitry, cause the component or circuitry to perform one or more steps or actions of any of the methods disclosed herein.

In an embodiment, the computer readable instructions includes applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible by a computing device, such as processor circuitry, etc., or other circuitry disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In an embodiment, memory can be integrated with a processor, separate from a processor, or external to a computing system.

Accordingly, blocks of the block diagrams and/or flowchart illustrations support various combinations for performing the specified functions, combinations of operations for performing the specified functions and program instructions for performing the specified functions. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

It will be appreciated that in one or more embodiments, the term computer or computing device can include, for example, any computing device or processing structure, including but not limited to a processor (e.g., a microprocessor), a central processing unit (CPU), a digital signal processor (DSP), an application-specific integrated circuit (ASIC), a field-programmable gate array (FPGA), a system on a chip (SoC), a graphics processing unit (GPU) or the like, or any combinations thereof.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

Although the method and various embodiments thereof have been described as performing sequential steps, the claimed subject matter is not intended to be so limited. As nonlimiting examples, the described steps need not be performed in the described sequence and/or not all steps are required to perform the method. Moreover, embodiments are contemplated in which various steps are performed in parallel, in series, and/or a combination thereof. As such, one of ordinary skill will appreciate that such examples are within the scope of the claimed embodiments.

In the detailed description herein, references to “one embodiment”, “an embodiment”, “an example embodiment”, “one or more embodiments”, “some embodiments”, etc., indicate that the embodiment or embodiments described may include a particular feature, structure, or characteristic, but every embodiment may not necessarily include the particular feature, structure, or characteristic. Moreover, such phrases are not necessarily referring to the same embodiment or embodiments. In addition, when a particular feature, structure, or characteristic is described in connection with an embodiment or embodiments, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

Where a range of values is provided, it is understood that each intervening value, to the tenth of the unit of the lower limit (unless the context clearly dictates otherwise), between the upper and lower limit of that range, and any other stated or intervening value in that stated range, is encompassed within the disclosure. The upper and lower limits of these smaller ranges may independently be included in the smaller ranges and are also encompassed within the disclosure, subject to any specifically excluded limit in the stated range. While the stated range includes one or both of the limits, ranges excluding either or both of those included limits are also included in the disclosure

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A method of providing a modifiable graphical user interface (GUI) for controlling a lock-in amplifier, wherein the GUI has a work surface and allows the user to add control elements to the work surface to obtain an application-specific GUI which is specifically adapted to a particular measurement application of the lock-in amplifier.

2. The method according to claim 1, wherein the control elements are assigned to different components of a measurement setup with which the measurement application is to be implemented.

3. The method according to claim 1, wherein the control elements are assigned to an input terminal of a device, a signal processing unit, a control unit, an input signal, and/or an output terminal of the device.

4. The method according to claim 1, wherein the control elements are displayed on the work surface as flat geometric figures.

5. The method according to claim 1, wherein control elements which have an observable influence in the current operating state of the lock-in amplifier are automatically added to the work surface.

6. The method according to claim 1, wherein at least one additional control element is automatically added to the work surface together with a control element selected by the user if a component assigned to the additional control element is required for the function of the selected control element.

7. The method according to claim 1, wherein the GUI enables the user to design a measurement process, validate a measurement configuration, and/or perform a measurement.

8. The method according to claim 1, wherein the GUI provides the user with templates for multiple measurement applications, and wherein the templates each comprise specific control elements necessary for the respective measurement application.

9. The method according to claim 1, wherein the GUI allows the user to select that at least one signal is to be sampled which flows through a component assigned to a selected control element or between two components assigned to two selected control elements.

10. A computer-readable storage medium storing instructions which, when executed by a computer processor, cause the computer processor to perform the method according to claim 1.

11. A lock-in amplifier comprising the computer-readable storage medium according to claim 10.

12. A lock-in amplifier comprising a processor configured to execute the method according to claim 1.
